(19) United States
(12) Patent Application Publication
(10) Pub. No.: US 2026/0182395 A1
(43) Pub. Date: Jun. 25, 2026

(54) STACKED PACKAGE STRUCTURE AND PACKAGE METHOD

(71) Applicant: JCET Group Co., LTD., Jiangyin (CN)

(72) Inventors: Zhuhe HUA, Jiangyin (CN); Kai LIU, Jiangyin (CN); Wenqi SHEN, Jiangyin (CN)

(21) Appl. No.: 19/412,531

(22) Filed: Dec. 8, 2025

(30) Foreign Application Priority Data
Dec. 24, 2024 (CN) 202411921928.3

(51) Int. Cl. H10W 70/20; H10W 70/00; H10W 70/65

(52) U.S. Cl. CPC H10W 70/20; H10W 70/099; H10W 70/65

(57) ABSTRACT

A stacked package structure and a package method are provided. The stacked package structure includes: a first package substrate having a first surface and a plurality of first welding surfaces, where a signal connection end is arranged on the first surface of the first package substrate; and a plurality of device structures each corresponding one of the plurality of first welding surfaces, where the plurality of first device structures are welded on the first welding surfaces of the first package substrate and electrically connected to the first package substrate.

### CROSS-REFERENCE TO RELATED APPLICATIONS

This application claims the benefit of priority to Chinese Application No. 202411921928.3, filed Dec. 24, 2024, which is incorporated herein by reference in its entirety.

### TECHNICAL FIELD

The present application is directed to the field of integrated circuit technology, and particularly relates to a stacked package structure and a package method.

### BACKGROUND

Today's highly integrated package technology enables compact layout for complex passive components, and package process plays a critical role in improving the performance and cost control of passive components. Existing package technologies include Ball Grid Array (BGA), Chip Scale Package (CSP), Wafer Level Package (WLP), 3D Package, and System in Package (SiP), and etc.

### SUMMARY

The present disclosure provides a stacked package structure and a package method.

The embodiment of the present disclosure provides a stacked package structure, which includes: a first package substrate including a first surface and a plurality of first welding surfaces, and a signal connection end is arranged on the first surface of the first package substrate; and a plurality of device structures corresponding one-to-one to the plurality of first welding surfaces, and welded on the first welding surfaces of the first package substrate, and electrically connected with the first package substrate.

In some implementations, the device structure includes any one of a chip package structure and a chip.

In some implementations, the plurality of first welding surfaces include a group of second surface and third surface arranged opposed to each other, the device structure includes a first package structure and a second package structure; the first package structure welded on the second surface of the first package substrate and electrically connected with the first package substrate; and the second package structure welded on the third surface of the first package substrate and electrically connected with the first package substrate.

In some implementations, the stacked package structure further includes: a first conductive connection structure located between the first package structure and the second surface of the first package substrate, which is used to weld the first package structure on the second surface of the first package substrate and achieve electrical connection between the first package structure and the first package substrate; and a second conductive connection structure located between the second package structure and the third surface of the second package substrate, which is used to weld the second package structure on the third surface of the first package substrate and achieve an electrical connection between the second package structure and the first package substrate.

In some implementations, the first surface is a side surface of the first package substrate, the second surface is a back surface of the first package substrate, and the third surface is a front surface of the first package substrate.

In some implementations, the first package structure and the second package structure respectively include: a second package substrate including a second welding surface; a first chip welded on the second welding surface of the second package substrate and electrically connected with the second package substrate; and a molding layer located on the second package substrate and covering the first chip.

In some implementations, the first package structure and the second package structure further respectively include: a third conductive connection structure located between the first chip and the second package substrate, which is used to weld the first chip on the second welding surface of the second package substrate and used to achieve an electrical connection between the first chip and the second package substrate.

In some implementations, the first package structure and the second package structure further respectively include: an underfill layer located between the first chip and the second package substrate and also filled in the gaps between the third conductive connection structures.

In some implementations, the first package structure and the second package structure further respectively include: a first passive component located above the second package substrate and electrically connected with the second package substrate.

In some implementations, the first package structure and the second package structure further respectively include: a second passive component located above the first chip and electrically connected with the second package substrate.

In some implementations, the first package structure and the second package structure further respectively include: a connection pillar located on the second package substrate exposed by the first chip, which is used to achieve electrical connection between the second passive component and the second package substrate.

In some implementations, the first package structure and the second package structure further respectively include: an adhesive layer located between the second passive component and the first chip, which is used to adhere the second passive component above the first chip.

In some implementations, the surface of the second package substrate away from the first surface of the first package substrate is a fourth surface; and the stacked package structure further includes: a third device structure welded together with the fourth surface of the second substrate of the first package structure and the fourth surface of the second substrate of the second package structure, respectively, and electrically connected with the second package substrate of the first package structure and the second package substrate of the second package structure, respectively.

In some implementations, the stacked package structure further includes: a fourth conductive connection structure located between the third device structure and the fourth surface of the second package substrate of the first package structure and the fourth surface of the second package substrate of the second package structure, which is used to weld the third device structure together with the fourth surface of the second package substrate of the first package structure and the fourth surface of the second package substrate of the second package structure, and achieving electrical connection of the third device structure with the second package substrate of the first package structure and the second package substrate of the second package structure.

In some implementations, the third device structure includes any one of a package structure, a chip, or a passive component.

Correspondingly, the embodiment of the present disclosure further provides a package method, which includes: providing a first package substrate including a first surface and a plurality of first welding surfaces, a signal connection end is arranged on the first surface of the first package substrate; providing a plurality of device structures, the plurality of device structures corresponding one-to-one to the plurality of first welding surfaces; and welding the plurality of device structures respectively on the welding surfaces of the first package substrate, and achieving electrical connections between the plurality of device structures and the first package substrate.

In some implementations, the device structure includes any one of a package structure and a chip.

In some implementations, the first welding surface includes a second surface and a third surface arranged opposed to each other; providing a plurality of device structures includes: providing a first package structure and a second package structure; and welding the plurality of device structures respectively on the welding surfaces of the first package substrate and achieving electrical connections between the plurality of device structures and the first package substrate includes: welding the first package structure and the second package structure on the second surface and the third surface of the first package substrate, respectively, and achieving electrical connections of the first package structure and the second package structure with the first package substrate, respectively.

In some implementations, in the step of providing the first package structure and the second package structure, the first package structure and the second package structure respectively include: a second package substrate including a welding surface; a first chip welded on the welding surface of the second package substrate and electrically connected with the second package substrate; a molding layer located on the second package substrate and covering the first chip.

In some implementations, the surface of the second package substrate away from the first surface of the first package substrate is a fourth surface; and the method further includes: providing a third device structure; after welding the first package structure and the second package structure on the second surface and the third surface of the first package substrate, respectively, and achieving electrical connections of the first package structure and the second package structure with the first package substrate, respectively, welding the third device structure together with the fourth surface of the second substrate of the first package structure and the fourth surface of the second substrate of the second package structure, respectively, and achieving electrical connections of the third device structure with the second package substrate of the first package structure and the second package substrate of the second package structure.

The embodiment of the present disclosure provides a stacked package structure, which includes: a first package substrate including a first surface and a plurality of first welding surfaces, and a signal connection end is arranged on the first surface of the first package substrate; and a plurality of device structures corresponding one-to-one to the plurality of first welding surfaces, and welded on the first welding surfaces of the first package substrate, and electrically connected with the first package substrate.

In the stacked package structure provided by the embodiment of the present disclosure, the first package substrate includes a plurality of first welding surfaces, and the first welding surface is welded with a corresponding device structures, respectively.

### BRIEF DESCRIPTION OF THE DRAWINGS

FIG. 1 is a structural schematic diagram of one embodiment of the stacked package structure provided by the present disclosure;

FIG. 2 is a structural schematic diagram of another embodiment of the stacked package structure provided by the present disclosure;

FIGS. 3 to 5 are intermediate structural schematic diagrams of structures formed in each step in one embodiment of the package method provided by the present disclosure; and

FIGS. 6 to 7 are intermediate structural schematic diagrams formed in each step in another embodiment of the package method provided by the present disclosure.

### DETAILED DESCRIPTION

The existing package structure has the problem of high cost and low integration level.

In order to solve the aforementioned technical problems, the embodiment of the present disclosure provides a stacked package structure, which includes: a first package substrate including a first surface and a plurality of first welding surfaces, and a signal connection end is arranged on the first surface of the first package substrate; and a plurality of device structures corresponding one-to-one to the plurality of first welding surfaces, and welded on the first welding surfaces of the first package substrate, and electrically connected with the first package substrate.

In the stacked package structure provided by the embodiment of the present disclosure, the first package substrate includes a plurality of first welding surfaces, and the first welding surface is welded with a corresponding device structures, respectively, and compared to existing methods of only welding device structures on one surface of the first package substrate, it can improve the integration level of the stacked package structure.

In order to make the above objects, characteristics, and advantages of the embodiments of the present disclosure more understandable, the specific embodiments of the present disclosure are described in detail below in conjunction with the accompanying drawings.

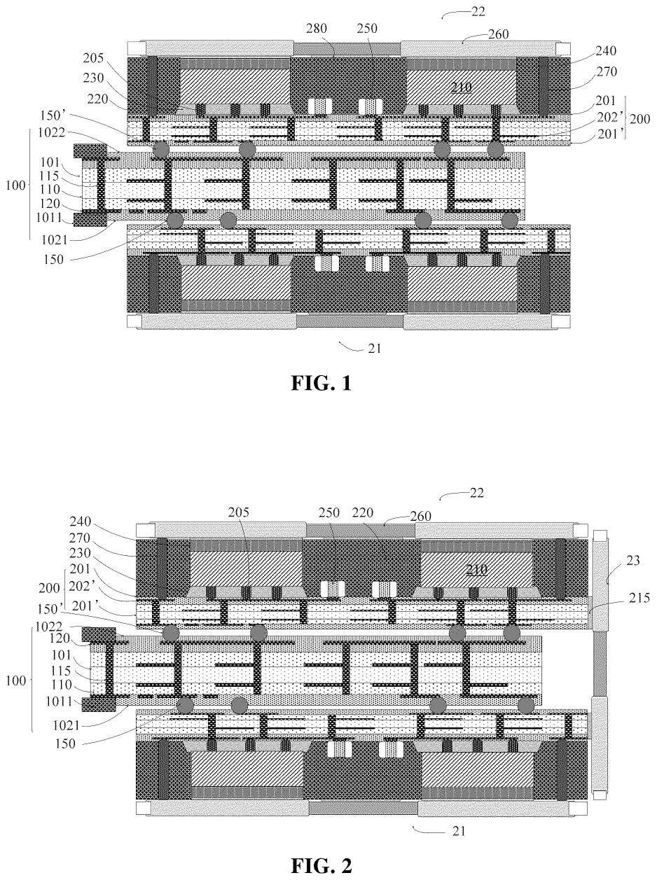

FIG. 1 is a structural schematic diagram of one embodiment of the stacked package structure provided by the present disclosure. Referring to FIG. 1, a stacked package structure includes: a first package substrate 100 including a first surface 101 and first welding surfaces 1021, second welding surfaces 1022, and a signal connection end 1011 is exposed on the first surface 101 of the first package substrate 100; a first package structure 21 welded on the first welding surface 1021 of the first package substrate 100 and electrically connected with the first package substrate 100; a second package structure 22 welded on the second welding surface 1022 of the first package substrate 100 and electrically connected with the first package substrate 100.

The first package substrate 100 is used to achieve welding with the first package structure 21 and the second package structure 22, thereby achieving package integration and electrical integration of the first package substrate 100 with the first package structure 21 and the second package structure 22.

In some implementations, the first package substrate 100 has in it conductive lines, the conductive lines are used to supply power or transmit electrical signals for a plurality of device structures, thereby achieving package integration of the plurality of device structures. Meanwhile, by integrated arrangement of a plurality of device structures on the first package substrate 100, it is conductive to improving the integration level of the stacked package structure.

In the present embodiment, the first package substrate 100 includes a first dielectric layer 110 and a first redistribution layer 120 located in the first dielectric layer 110.

The first dielectric layer 110 is used to achieve electrical isolation between the first redistribution layers 120, thereby reducing the risk of leakage current between adjacent first redistribution layers 120.

As an example, the material of the first dielectric layer 110 includes one or more of silicon oxide, silicon nitride, silicon nitride oxide, and polyimide.

The first redistribution layer 120 is used to be electrically connected with a plurality of device structures, and through the first redistribution layer 120, input ports and output ports on a plurality of device structures can be redistributed, which helps to improve the flexibility of electrical signal connections and helps to reduce the path length of electrical signal transmission, and reduce the transmission delay of electrical signals.

As an example, the material of the first redistribution layer 120 is copper. In other embodiments, the material of the redistribution layer may also be at least one of aluminum and silver.

In the present embodiment, interconnection through-via structures 115 are arranged in the first dielectric layer 110 between adjacent first redistribution layers 120. Through the interconnection through-via structures 115, electrical connections between adjacent first redistribution layers 120 can be achieved.

As an example, the material of the interconnection through-via structure 115 is copper. In other embodiments, the material of the first interconnection through-via structure can also be tungsten, cobalt, or tungsten-cobalt alloy, and etc., which can be arranged by those skilled in the art according to actual requirements, and no limitation is imposed herein.

In the present embodiment, the first package substrate 100 includes a first surface 101. In some implementations, the first surface 101 of the first package substrate 100 is a side surface of the first package substrate 100.

The first surface 101 of the first package substrate 100 is used to achieve signal transmission between the stacked package structure and the outside. In some implementations, a signal connection end 1011 is exposed on the first surface 101 of the first package substrate 100, and the signal connection end 1011 is used to achieve signal transmission between the first package substrate 100 and the outside, thereby achieving signal transmission between the stacked package structure and the outside. It should be understood that the signal connection end 1011 may be arranged on the first surface 101 of the first package substrate 100, and may also be arranged on the end of the first welding surfaces 1021 and second welding surfaces 1022 of the first package substrate 100 close to the first surface 101.

In the present embodiment, the first package substrate 100 further includes a group of first welding surfaces 1021 and second welding surfaces 1022 arranged opposed to each other. In some implementations, the first welding surfaces 1021 and second welding surfaces 1022 are the second surface and the third surface of the first package substrate 100, respectively. Wherein the second surface of the first package substrate 100 is the back surface of the first package substrate 100, and the third surface of the first package substrate 100 is the front surface of the first package substrate 100.

In the present embodiment, the first welding surface 1021 of the first package substrate 100 is used to achieve welding with the first package structure 21, and the second welding surface 1022 of the first package substrate 100 is used to achieve welding with the second package structure 22.

In the present embodiment, the first package substrate 100 includes an organic substrate or a glass substrate with circuits.

Referring to FIG. 1, in the present embodiment, the first package structure 21 and the second package structure 22 respectively include: a second package substrate 200 including a second welding surface 201; a first chip 210 welded on the second welding surface 201 of the second package substrate 200 and electrically connected with the second package substrate 200; and a molding layer 220 located on the second package substrate 200 and covering the first chip 210.

The second package substrate 200 is used to provide a process platform for packaging the first chip 210.

In the present embodiment, the second package substrate 200 includes a second dielectric layer 201′ and a second redistribution layer 202′ in the second dielectric layer.

As an example, the material of the second dielectric layer 201′ includes one or more of silicon oxide, silicon nitride, silicon nitride oxide, and polyimide.

The second redistribution layer 202′ is used to be electrically connected with the first chip 210, through the second redistribution layer 202′, the input port and output port on the first chip 210 can be redistributed, thereby helping to improve the flexibility of electrical signal connections, and it is conductive to reducing the path length of electrical signal transmission and decreasing the transmission delay of electrical signals.

The second redistribution layer 202′ is also used to be electrically connected with the first package substrate 100, thereby achieving electrical connections of the first package structure 21 and the second package structure 22 with the first package substrate 100.

As an example, the second package substrate 200 may be one of a silicon substrate, a Re-distribution Layer (RDL) substrate, a resin substrate, a Printed Circuit Board (PCB), a ceramic substrate, a glass substrate, or a Flexible Printed Circuit Board (FPC). As an example, the second package substrate 200 may be a single-layer board or a multi-layer board.

The first chip 210 is used to achieve package integration and electrical integration with the second package substrate 200 to form a corresponding package structure to meet corresponding functional requirements.

In some implementations, the first chip 210 may be manufactured using integrated circuit manufacturing technology. The first chip 210 typically includes devices such as NMOS devices and/or PMOS devices, and etc., formed on a semiconductor substrate.

For example, the first chip 210 may be one or more of a System-on-Chip (SoC), a memory chip, an Application-Specific Integrated Circuit (ASIC) chip, a Central Processing Unit (CPU) chip, a Graphics Processing Unit (GPU) chip, and an Field-Programmable Gate Array (FPGA) chip.

According to actual requirements, the number of first chips 210 may be one or more. Wherein in the case where the number of first chips 210 is multiple, the functions of the plurality of first chips 210 are different.

Referring again to FIG. 1, in the present embodiment, the first chip 210 is welded on the second welding surface 201 of the second package substrate 200. In some implementations, the first package structure 21 and the second package structure 22 respectively further include: a third conductive connection structure 205 located between the first chip 210 and the second package substrate 200, which is used to weld the first chip 210 on the second welding surface 201 of the second package substrate 200 and used to achieve an electrical connection between the first chip 210 and the second package substrate 200.

The third conductive connection structure 205 is used to lead out the electrical properties of the first chip 210 and used to achieve arrangement of the first chip 210 on the topmost second redistribution layer 202′, which reduces the risk of separation of the first chip 210 and the second redistribution layer 202′ from each other. Meanwhile, the third conductive connection structure 205 is also used to achieve an electrical connection between the first chip 210 and the second redistribution layer 202′, so that the first chip 210 can be electrically connected with the second package substrate 200 through the third conductive connection structure 205.

In the present embodiment, the third conductive connection structure 205 is a conductive bump.

In some implementations, in the process of forming the first package structure and the second package structure, the third conductive connection structure 205 is formed using a conductive bump process.

As an example, the material of the third conductive connection structure 205 includes one or more of gold, lead-tin, silver-tin, gold-tin, and copper-tin.

In other embodiments, the back surface of the first chip is mounted with the front surface of the second package substrate, and electrical connection with the second package substrate is achieved through leads. In some implementations, the leads are metallic wires, and one end of the leads is connected with the first chip, and the other end is connected with the interconnection structure layer in the second package substrate, thereby achieving electrical connection between the first chip and the second package substrate.

Referring again to FIG. 1, in the present embodiment, the first package structure 21 and the second package structure 22 respectively further include: an underfill layer 230 located between the first chip 210 and the second package substrate 200, and also filled in the gaps between the third conductive connection structures 205.

The underfill layer 230 can protect the first chip 210 from outside influences, which can reduce the impact of thermal expansion coefficient mismatch between the first chip 210 and the second package substrate 200, and it is possible to redistribute stress and strain to avoid the failure of the third conductive connection structure 205, and it is conductive to improving the reliability of welding between the first chip 210 and the second welding surface 201 of the second package substrate 200, and thus it is conductive to improving the reliability of the obtained package structure.

As an example, the material of the underfill layer 230 includes epoxy resin. In other embodiments, the material of the underfill layer may also be made of other thermosetting materials, which can be selected by those skilled in the art according to actual requirements, and no limitation is imposed herein.

Referring again to FIG. 1, in the present embodiment, the first package structure 21 and the second package structure 22 respectively further include: a heat dissipation layer 240 formed on the first chip 210, which is used to conduct heat generated during the operation of the first chip 210 to the outside.

The heat dissipation layer 240 is used to conduct heat generated during the operation of the first chip 210 to the outside, which can prevent damage to the first chip 210 caused by the accumulation of heat generated during the operation of the first chip 210, thereby providing protection for the first chip 210.

In the present embodiment, the material of the heat dissipation layer 240 is copper, copper has superior thermal conductivity and can quickly conduct the heat generated by the first chip 210 during operation to the outside world, which is conducive to improving heat dissipation efficiency.

In other embodiments, the heat dissipation layer may also be made of metallic materials or alloy materials suitable for use as heat sinks, such as aluminum, gold, nickel, steel, or stainless steel, and etc.

Referring again to FIG. 1, in the present embodiment, the first package structure 21 and the second package structure 22 respectively further include: a first passive component 250 located on the second welding surface 201 of the second package substrate 200 exposed by the first chip 210 and electrically connected with the second package substrate 200.

The first passive component 250 is a passive device. Passive devices are passive components that exhibit their characteristics without requiring an external power source, which primarily include resistive devices, inductive devices, and capacitive devices, such as at least one of resistors, capacitors, inductors, converters, tapers, matching networks, resonators, filters, mixers, and switches, and etc.

The first passive component 250 may be welded together with the second welding surface 201 of the second package substrate 200 through bumps, and achieve an electrical connection with the second package substrate 200. In other embodiments, other implementable methods may also be used for welding.

The molding layer 220 is used to seal within it the first chip 210 and the first passive component 250, so that it can serve for sealing the first chip 210 and the first passive component 250, which can reduce the probability of damage to, contamination of, or oxidation of the first chip 210 and the first passive component 250.

The molding layer 220 is made of a molding material, the strength of the molding material is high, which can correspondingly improve the strength of the molding layer 220, thereby facilitating the improvement of the overall strength of the package structure.

In the present embodiment, the material of the molding layer 220 is epoxy resin. Epoxy resin has the advantages of low shrinkage, good adhesion, good corrosion resistance, superior electrical properties, and low cost, and etc., therefore, it is widely used as a package material for electronic devices and integrated circuits.

In other embodiments, the material of the molding layer may also be other suitable materials, such as thermosetting materials, for example, polyimide or silicone rubber, and etc.

In the present embodiment, the top surface of the heat dissipation layer 240 is exposed by the molding layer 220, so that it is able to conduct the heat generated by the first chip 210 during operation to the outside quickly, which is conductive to improving heat dissipation efficiency.

Referring again to FIG. 1, in the present embodiment, the first package structure 21 and the second package structure 22 respectively further include: a second passive component 260 located above the first chip 210 and electrically connected with the second package substrate 200.

The second passive component 260 is located above the first chip 210, i.e., the second passive component 260 and the first chip 210 are arranged stacked on top of one another along the longitudinal direction, and compared to the case where the first chip 210 and the second passive component 260 are arranged side-by-side along the horizontal direction, it can reduce the area occupied by the second passive component 260 on the second package substrate 200 and reduce the volume of the package structure, and correspondingly it helps to improve the integration level of the package structure and contributes to reduction of the cost of the package structure.

In the present embodiment, a heat dissipation layer 240 is formed on the first chip 210, and in the case where the top surface of the heat dissipation layer 240 is exposed by the molding layer 220, the second passive component 260 is located above the molding layer 220 and the heat dissipation layer 240.

As an example, the second passive component 260 is an inductor. In other embodiments, the second passive component may also be at least one of a capacitor, resistor, converter, taper, matching network, resonator, filter, mixer, and switch, and etc.

Referring again to FIG. 1, in the present embodiment, the first package structure 21 and the second package structure 22 respectively further include: a connection pillar 270 located on the second package substrate 200 exposed by the first chip 210, which is used to achieve an electrical connection between the second passive component 260 and the second package substrate 200.

In some implementations, one end of the connection pillar 270 is electrically connected with the second package substrate 200, and the other end of the connection pillar 270 is electrically connected with the second passive component 260, thereby achieving electrical connection between the second passive component 260 and the second package substrate 200.

In the present embodiment, the material of the connection pillar 270 is copper. In other embodiments, the material of the connection pillar may also be other metallic materials such as aluminum, tin, silver, and etc.

In the present embodiment, the number of connection pillars 270 is multiple, and the plurality of connection pillars 270 are arranged at intervals from each other.

In the present embodiment, the molding layer 220 also covers the sidewalls of the connection pillars 270, so that it can serve to seal the connection pillars 270, thereby reducing the probability of damage to, contamination of, or oxidation of the connection pillars 270.

Referring again to FIG. 1, in the present embodiment, the first package structure 21 and the second package structure 22 respectively further include: an adhesive layer 280 located between the second passive component 260 and the first chip 210, which is used to adhere the second passive component 260 on the molding layer 220.

The adhesive layer 280 is used to adhere the second passive component 260 on the molding layer 220, thereby further improving the fixation strength of the second passive component 260.

In the present embodiment, a heat dissipation layer 240 is further arranged above the first chip 210, and in the case where the top surface of the heat dissipation layer 240 is exposed by the molding layer 220, the adhesive layer 280 is located between the second passive component 260 and the heat dissipation layer 240 as well as the molding layer 220.

In the present embodiment, the material of the adhesive layer 280 includes one or two of a resin adhesive and a double-sided adhesive film.

Taking the case where the structures of the first package structure and the second package structure are the same as an example, the first device structure and the second device structure in the embodiments of the present disclosure are described above. It should be understood that the first package structure and the second package structure may also be different, and no limitation is imposed herein.

Taking the case where the first package structure and the second package structure are package structures formed using Ball Grid Array (BGA) package process respectively as an example, the first package structure and the second package structure are described above. In other embodiments, the first package structure and the second package structure may also be package structures formed using package processes such as chip-scale package, wafer-level package, 3D package, and system-in-package, respectively, and no limitation is imposed herein.

Referring again to FIG. 1, the stacked package structure further includes: a first conductive connection structure 150 located between the first package structure 21 and the second surface of the first package substrate 100, which is used to weld the first package structure 21 on the second surface of the first package substrate 100 and achieve an electrical connection between the first package structure 21 and the first package substrate 100.

As an example, the first conductive connection structure 150 is a solder ball or a bump. As an embodiment, the material of the solder ball includes tin. In other embodiments, other implementable methods may also be used for connection and no limitation is imposed herein.

Correspondingly, the first conductive connection structure 150 is formed using a ball planting process or a conductive bump process.

Referring again to FIG. 1, the stacked package structure further includes: a second conductive connection structure 150′ located between the second package structure 22 and the third surface of the first package substrate 100, which is used to weld the second package structure 22 on the third surface of the first package substrate 100 and achieve an electrical connection between the second package structure 22 and the first package substrate 100.

As an example, the second conductive connection structure 150′ is a solder ball or bump. In other embodiments, other implementable methods may also be used for connection and no limitation is imposed herein.

Correspondingly, the second conductive connection structure 150′ is formed using a ball planting process or a conductive bump process.

The stacked package structure in the embodiments of the present disclosure is described above with a plurality of device structures including a first package structure and a second package structure. It should be understood that at least one of the first package structure and the second package structure can also be a chip.

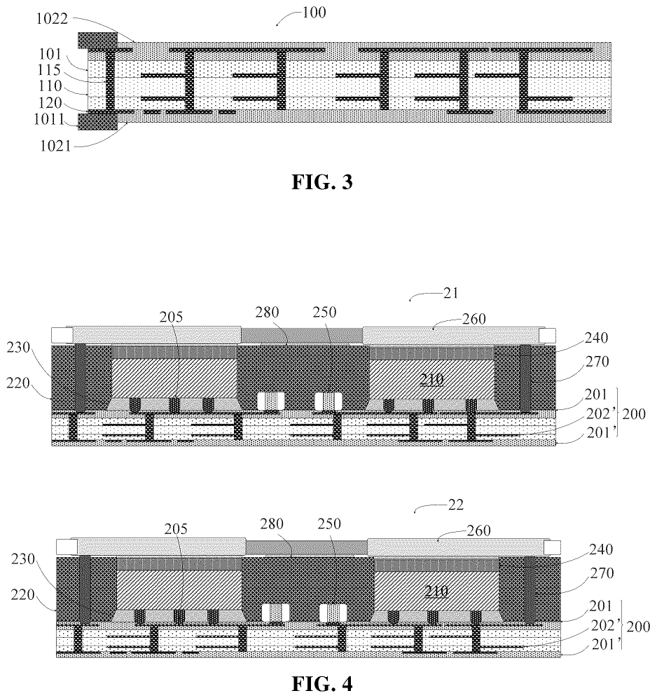

FIG. 2 illustrates a structural schematic diagram of another embodiment of the stacked package structure provided by the present disclosure. The similarities between the present embodiment and the aforementioned embodiment will not be repeated herein. Referring to FIG. 2, the difference between the present embodiment and the aforementioned embodiment lies in: the surface of the second package substrate 200 away from the first surface 101 of the first package substrate 100 is the fourth surface; the stacked package structure further includes: a second chip 23 welded together with the fourth surface of the second package substrate 200 of the first package structure 21 and the fourth surface of the second package substrate 200 of the second package structure 22, respectively, and electrically connected with the second package substrate 200 of the first package structure 21 and the second package substrate 200 of the second package structure 22, respectively.

In the present embodiment, the second chip 23 is different from the first chip 210 in the first package structure 21 and the first chip 210 in the second package structure 22, respectively.

The second chip 23 is electrically connected with the second package substrate 200 of the first package structure 21 and the second package substrate 200 of the second package structure 22, respectively, thereby achieving electrical connection between the first package structure 21 and the second package structure 22.

Referring again to FIG. 1, in the present embodiment, the stacked package structure further includes: a fourth conductive connection structure 215 located between the second chip 23 and the fourth surface of the second package substrate 200 of the first package structure 21 and the fourth surface of the second package substrate 200 of the second package structure 22, which is used to weld the second chip 23 together with the fourth surface of the second package substrate 200 of the first package structure 21 and the fourth surface of the second package substrate 200 of the second package structure 22, and achieve an electrical connection of the second chip 23 with the second package substrate 200 of the first package structure 21 and the second package substrate 200 of the second package structure 22.

As an example, the fourth conductive connection structure 215 is a solder ball or a bump. In other embodiments, other implementable methods may also be used for connection and no limitation is imposed herein.

The second chip 23 is welded together with the fourth surface of the second package substrate 200 of the first package structure 21 and the fourth surface of the second package substrate 200 of the second package structure 22, respectively, and is electrically connected with the second package substrate 200 of the first package structure 21 and the second package substrate 200 of the second package structure 22, respectively, which is conductive to further improving the integration level of the stacked package structure.

The stacked package structure in the embodiments of the present disclosure has been described using the third device structure as the second chip 23 as an example. In other embodiments, the third device structure may also be a package structure or a passive component.

Correspondingly, the present disclosure also provides a package method.

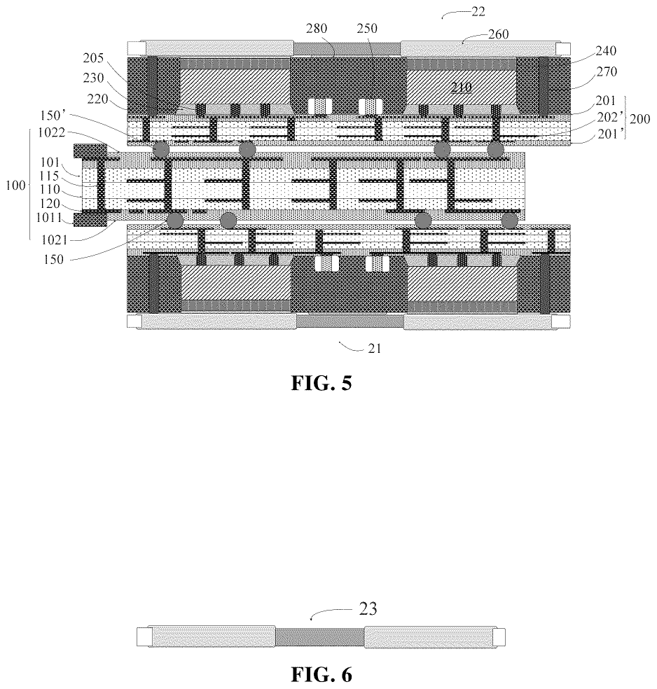

FIGS. 3 to 5 illustrate intermediate structural schematic diagrams of structures formed in each step in one embodiment of the package method provided by the present disclosure.

Referring to FIG. 3, a first package substrate 100 is provided, which includes a first surface 101 and first welding surfaces 1021, second welding surfaces 1022, and a signal connection end 1011 is arranged on the first surface 101 of the first package substrate 100.

The first package substrate 100 provides a process platform for forming the stacked package structure.

In the present embodiment, the first package substrate 100 is used to achieve welding with the first package structure 21 and the second package structure 22, thereby realizing package integration and electrical integration between the first package substrate 100 and the first package structure 21 as well as the second package structure 22.

In the step of providing the first package substrate 100, the first package substrate 100 has in it conductive lines, the conductive lines are used to supply power or transmit electrical signals for a plurality of device structures, thereby achieving package integration of the plurality of device structures. Meanwhile, by integrated arrangement of a plurality of device structures on the first package substrate 100, it is conductive to improving the integration level of the stacked package structure.

In the present embodiment, the first package substrate 100 includes a first dielectric layer 110 and a first redistribution layer 120 located in the first dielectric layer 110.

The first dielectric layer 110 is used to achieve electrical isolation between the first redistribution layers 120, thereby reducing the risk of leakage current between adjacent first redistribution layers 120.

As an example, the material of the first dielectric layer 110 includes one or more of silicon oxide, silicon nitride, silicon nitride oxide, and polyimide.

The first redistribution layer 120 is used to be electrically connected with a plurality of device structures, and through the first redistribution layer 120, input ports and output ports on a plurality of device structures can be redistributed, which can improve the flexibility of electrical signal connections and help to reduce the path length of electrical signal transmission and reduce the transmission delay of electrical signals.

As an example, the material of the first redistribution layer 120 is copper. In other embodiments, the material of the redistribution layer may also be at least one of aluminum and silver.

In the present embodiment, in the step of providing the first package substrate 100, interconnection through-via structures 115 are arranged in the first dielectric layer 110 between adjacent first redistribution layers 120. Through the interconnection through-via structures 115, electrical connections between adjacent first redistribution layers 120 can be achieved.

As an example, the material of the interconnection through-via structure 115 is copper. In other embodiments, the material of the first interconnection through-via structure can also be tungsten, cobalt, or tungsten-cobalt alloy, and etc., which can be configured by those skilled in the art according to actual requirements, and no limitation is imposed herein.

In the present embodiment, the first package substrate 100 includes a first surface 101. In some implementations, the first surface 101 of the first package substrate 100 is a side surface of the first package substrate 100.

The first surface 101 of the first package substrate 100 is used to achieve signal transmission between the stacked package structure and the outside. In some implementations, a signal connection end 1011 is arranged on the first surface 101 of the first package substrate 100, and the signal connection end 1011 is used to achieve signal transmission between the first package substrate 100 and the outside, thereby achieving signal transmission between the stacked package structure and the outside.

In the present embodiment, the first package substrate 100 further includes first welding surfaces 1021 and second welding surfaces 1022. In some implementations, the first welding surfaces 1021 and second welding surfaces 1022 are the second surface and the third surface of the first package substrate 100, respectively. Wherein the second surface of the first package substrate 100 is the back surface of the first package substrate 100, and the third surface of the first package substrate 100 is the front surface of the first package substrate 100.

In the present embodiment, the first welding surface 1021 of the first package substrate 100 is used to achieve welding with the first package structure 21, and the first welding surface 1021 of the first package substrate 100 is used to achieve welding with the second package structure 22.

In the present embodiment, the first package substrate 100 includes an organic substrate or a glass substrate with circuits.

Referring to FIG. 4, a first package structure 21 and a second package structure 22 are provided.

In the present embodiment, in the step of providing the first package structure 21 and the second package structure 22, the first package structure 21 and the second package structure 22 respectively include: a second package substrate 200 including a second welding surface 201; a first chip 210 welded on the second welding surface 201 of the second package substrate 200 and electrically connected with the second package substrate 200; and a molding layer 220 located on the second package substrate 200 and covering the first chip 210.

The second package substrate 200 is used to provide a process platform for packaging the first chip 210.

In the present embodiment, the second package substrate 200 includes a second dielectric layer 201′ and a second redistribution layer 202′ in the second dielectric layer.

As an example, the material of the second dielectric layer 201′ includes one or more of silicon oxide, silicon nitride, silicon nitride oxide, and polyimide.

The second redistribution layer 202′ is used to be electrically connected with the first chip 210, and through the first redistribution layer 120, the input port and output port on the first chip 210 can be redistributed, thereby helping to improve the flexibility of electrical signal connections, and it is conductive to reducing the path length of electrical signal transmission and decreasing the transmission delay of electrical signals.

The second redistribution layer 202′ is also used to be electrically connected with the first package substrate 100, thereby achieving electrical connections of the first package structure 21 and the second package structure 22 with the first package substrate 100.

As an example, the second package substrate 200 may be one of a silicon substrate, a Re-distribution Layer (RDL) substrate, a resin substrate, a Printed Circuit Board (PCB), a ceramic substrate, a glass substrate, or a Flexible Printed Circuit Board (FPC). As an example, the second package substrate 200 may be a single-layer board or a multi-layer board.

The first chip 210 is used to achieve package integration and electrical integration with the second package substrate 200 to form a corresponding package structure to meet corresponding functional requirements.

In some implementations, the first chip 210 may be manufactured using integrated circuit manufacturing technology. The first chip 210 typically includes devices such as NMOS devices and/or PMOS devices, and etc., formed on a semiconductor substrate.

For example, the first chip 210 may be one or more of a system-on-chip (SoC), a memory chip, an Application-Specific Integrated Circuit (ASIC) chip, a Central Processing Unit (CPU) chip, a Graphics Processing Unit (GPU) chip, and an Field-Programmable Gate Array (FPGA) chip.

According to actual requirements, the number of first chips 210 may be one or more. Wherein in the case where the number of first chips 210 is multiple, the functions of the plurality of first chips 210 are different.

In the present embodiment, in the step of providing the first package structure 21 and the second package structure 22, the first chip 210 is welded on the second welding surface 201 of the second package substrate 200. In some implementations, the first package structure 21 and the second package structure 22 respectively further include: a third conductive connection structure 205 located between the first chip 210 and the second package substrate 200, which is used to weld the first chip 210 on the second welding surface 201 of the second package substrate 200 and used to achieve an electrical connection between the first chip 210 and the second package substrate 200.

The third conductive connection structure 205 is used to lead out the electrical properties of the first chip 210 and used to achieve arrangement of the first chip 210 on the topmost second redistribution layer 202′, which reduces the risk of separation of the first chip 210 and the second redistribution layer 202′ from each other. Meanwhile, the third conductive connection structure 205 is also used to achieve an electrical connection between the first chip 210 and the second redistribution layer 202′, so that the first chip 210 can be electrically connected with the second package substrate 200 through the third conductive connection structure 205.

In the present embodiment, the third conductive connection structure 205 is a conductive bump.

In some implementations, in the process of forming the first package structure and the second package structure, the third conductive connection structure 205 is formed using a conductive bump process.

As an example, the material of the third conductive connection structure 205 includes one or more of gold, lead-tin, silver-tin, gold-tin, and copper-tin.

In other embodiments, in the step of providing the package structure and the second package structure, the back surface of the first chip is mounted with the front surface of the second package substrate, and electrical connection with the second package substrate is achieved through leads. In some implementations, the leads are metallic wires, and one end of the leads is connected with the first chip, and the other end is connected with the interconnection structure layer in the second package substrate, thereby achieving electrical connection between the first chip and the second package substrate.

In the present embodiment, in the step of providing the first package structure 21 and the second package structure 22, the first package structure 21 and the second package structure 22 respectively further include: an underfill layer 230 located between the first chip 210 and the second package substrate 200, and also filled in the gaps between the third conductive connection structures 205.

The underfill layer 230 can protect the first chip 210 from outside influences, which can reduce the impact of thermal expansion coefficient mismatch between the first chip 210 and the second package substrate 200, and it is possible to redistribute stress and strain to avoid the failure of the third conductive connection structure 205, and it is conductive to improving the reliability of welding between the first chip 210 and the second welding surface 201 of the second package substrate 200, and thus it is conductive to improving the reliability of the obtained package structure.

As an example, the material of the underfill layer 230 includes epoxy resin. In other embodiments, the material of the first underfill layer may also be made of other thermosetting materials, which can be selected by those skilled in the art according to actual requirements, and no limitation is imposed herein.

As an example, the underfill layer 230 is formed using an underfill process. In other embodiments, the underfill layer may also be formed using other processes, and no limitation is imposed herein.

In the present embodiment, in the step of providing the first package structure 21 and the second package structure 22, the first package structure 21 and the second package structure 22 respectively further include: a heat dissipation layer 240 formed on the first chip 210, which is used to conduct heat generated during the operation of the first chip 210 to the outside.

The heat dissipation layer 240 is used to conduct heat generated during the operation of the first chip 210 to the outside, which can prevent damage to the first chip 210 caused by the accumulation of heat generated during the operation of the first chip 210, thereby providing protection for the first chip 210.

In the present embodiment, the material of the heat dissipation layer 240 is copper, copper has superior thermal conductivity and can quickly conduct the heat generated by the first chip 210 during operation to the outside world, which is conducive to improving heat dissipation efficiency.

In other embodiments, the heat dissipation layer may also be made of metallic materials or alloy materials suitable for use as heat sinks, such as aluminum, gold, nickel, steel, or stainless steel, and etc.

In the present embodiment, in the step of providing the first package structure 21 and the second package structure 22, the first package structure 21 and the second package structure 22 respectively further include: a first passive component 250 located on the second welding surface 201 of the second package substrate 200 exposed by the first chip 210 and electrically connected with the second package substrate 200.

The first passive component 250 is a passive device. Passive devices are passive components that exhibit their characteristics without requiring an external power source, which primarily include resistive devices, inductive devices, and capacitive devices, such as at least one of resistors, capacitors, inductors, converters, tapers, matching networks, resonators, filters, mixers, and switches, and etc.

The first passive component 250 may be welded together with the second welding surface 201 of the second package substrate 200 through bumps, and achieve an electrical connection with the second package substrate 200. In other embodiments, other implementable methods may also be used for welding.

The molding layer 220 is used to seal within it the first chip 210 and the first passive component 250, so that it can serve for sealing the first chip 210 and the first passive component 250, which can reduce the probability of damage to, contamination of, or oxidation of the first chip 210 and the first passive component 250.

The molding layer 220 is made of a molding material, the strength of the molding material is high, which can correspondingly improve the strength of the molding layer 220, thereby facilitating the improvement of the overall strength of the package structure.

In the present embodiment, the material of the molding layer 220 is epoxy resin. Epoxy resin has the advantages of low shrinkage, good adhesion, good corrosion resistance, superior electrical properties, and low cost, and etc., therefore, it is widely used as a package material for electronic devices and integrated circuits.

In other embodiments, the material of the molding layer may also be other suitable materials, such as thermosetting materials, for example, polyimide or silicone rubber, and etc.

In the present embodiment, the top surface of the heat dissipation layer 240 is exposed by the molding layer 220 so that it is able to conduct the heat generated by the first chip 210 during operation to the outside quickly, which is conductive to improving heat dissipation efficiency.

In the present embodiment, in the step of providing the first package structure 21 and the second package structure 22, the first package structure 21 and the second package structure 22 respectively further include: a second passive component 260 located above the first chip 210 and electrically connected with the second package substrate 200.

The second passive component 260 is located above the first chip 210, i.e., the second passive component 260 and the first chip 210 are arranged stacked on top of one another along the longitudinal direction, and compared to the case where the first chip 210 and the second passive component 260 are arranged side-by-side along the horizontal direction, it can reduce the area occupied by the second passive component 260 on the second package substrate 200 and reduce the volume of the package structure, and correspondingly it helps to improve the integration level of the package structure and contributes to reduction of the cost of the package structure.

In the present embodiment, a heat dissipation layer 240 is formed on the first chip 210, and in the case where the top surface of the heat dissipation layer 240 is exposed by the molding layer 220, the second passive component 260 is located above the molding layer 220 and the heat dissipation layer 240.

As an example, the second passive component 260 is an inductor. In other embodiments, the second passive component may also be at least one of a capacitor, resistor, converter, taper, matching network, resonator, filter, mixer, and switch, and etc.

In the present embodiment, in the step of providing the first package structure 21 and the second package structure 22, the first package structure 21 and the second package structure 22 respectively further include: a connection pillar 270 located on the second package substrate 200 exposed by the first chip 210, which is used to achieve an electrical connection between the second passive component 260 and the second package substrate 200.

In some implementations, one end of the connection pillar 270 is electrically connected with the second package substrate 200, and the other end of the connection pillar 270 is electrically connected with the second passive component 260, thereby achieving electrical connection between the second passive component 260 and the second package substrate 200.

In the present embodiment, the material of the connection pillar 270 is copper. In other embodiments, the material of the connection pillar may also be other metallic materials such as aluminum, tin, silver, and etc.

In the present embodiment, the number of connection pillars 270 is multiple, and the plurality of connection pillars 270 are arranged at intervals from each other.

In the present embodiment, the molding layer 220 also covers the sidewalls of the connection pillars 270, so that it can serve to seal the connection pillars 270, thereby reducing the probability of damage to, contamination of, or oxidation of the connection pillars 270.

In the present embodiment, in the step of providing the first package structure 21 and the second package structure 22, the first package structure further includes: an adhesive layer 280 located between the second passive component 260 and the first chip 210, which is used to adhere the second passive component 260 on the molding layer 220.

The adhesive layer 280 is used to adhere the second passive component 260 on the molding layer 220, thereby further improving the fixation strength of the second passive component 260.

In the present embodiment, a heat dissipation layer 240 is further arranged above the first chip 210, and in the case where the top surface of the heat dissipation layer 240 is exposed by the molding layer 220, the adhesive layer 280 is located between the second passive component 260 and the heat dissipation layer 240 as well as the molding layer 220.

In the present embodiment, the material of the adhesive layer 280 includes one or two of a resin adhesive and a double-sided adhesive film.

Taking the case where the structures of the first package structure and the second package structure are the same as an example, the first device structure and the second device structure in the embodiments of the present disclosure are described above. It should be understood that the first package structure and the second package structure may also be different, and no limitation is imposed herein.

Taking the case where the first package structure and the second package structure are package structures formed using Ball Grid Array (BGA) package process respectively as an example, the first package structure and the second package structure are described above. In other embodiments, the first package structure and the second package structure may also be package structures formed using package processes such as chip-scale package, wafer-level package, 3D package, and system-in-package, respectively, and no limitation is imposed herein.

Referring to FIG. 5, the first package structure 21 and the second package structure 22 are respectively welded on the first welding surfaces 1021 and second welding surfaces 1022 of the first package substrate 100, and achieve electrical connections of the first package structure 21 and the second package structure 22 with the first package substrate 100, respectively.

In the present embodiment, the first welding surface of the first package substrate 100 includes the second surface and third surface of the first package substrate 100, and the plurality of device structures include a first package structure 21 and a second package structure 22.

Correspondingly, the step of respectively welding the first package structure 21 and the second package structure 22 on the first welding surfaces 1021 and second welding surfaces 1022 of the first package substrate 100, and respectively achieving electrical connections of the first package structure 21 and the second package structure 22 with the first package substrate 100 includes: welding the first package structure 21 on the second surface of the first package substrate 100, welding the second package structure 22 on the third surface of the first package substrate 100, and achieving electrical connections of the first package structure 21 and the second package structure 22 with the first package substrate 100, respectively.

In the present embodiment, the step of welding the first package structure 21 on the second surface of the first package substrate 100 and achieving an electrical connection between the first package structure 21 and the first package substrate 100 includes: arranging a first conductive connection structure 150 between the second package substrate 200 of the first package structure 21 and the first package substrate 100; welding the first package structure 21 on the second surface of the first package substrate 100 through the first conductive connection structure 150 and achieving an electrical connection between the first package structure 21 and the first package substrate 100.

Wherein the step of arranging the first conductive connection structure 150 between the second package substrate 200 of the first package structure 21 and the first package substrate 100 includes: forming the first conductive connection structure 150 on a surface of the second package substrate 200 of the first package structure 21 facing the second surface of the first package substrate 100, or forming the first conductive connection structure 150 on the second surface of the first package substrate 100, or forming a first sub-conductive connection structure on a surface of the second package substrate 200 of the first package structure 21 facing the second surface of the first package substrate 100, and forming a second sub-conductive connection structure on the second surface of the first package substrate 100, and the first sub-conductive connection structure and the second sub-conductive connection structure constitute the first conductive connection structure 150.

The step of welding the second package structure 22 on the third surface of the first package substrate 100 and achieving an electrical connection between the second package structure 22 and the first package substrate 100 includes: arranging a second conductive connection structure 150′ between the second package substrate 200 of the second package structure 22 and the first package substrate 100; welding the second package structure 22 on the third surface of the first package substrate 100 through the second conductive connection structure 150′, and achieving an electrical connection between the second package structure 22 and the first package substrate 100.

Wherein the step of arranging the second conductive connection structure 150′ between the second package substrate 200 of the second package structure 22 and the first package substrate 100 includes: forming the second conductive connection structure 150′ on a surface of the second package substrate 200 of the second package structure 22 facing the third surface of the first package substrate 100, or forming the second conductive connection structure 150′ on the third surface of the first package substrate 100, or forming a third sub-conductive connection structure on a surface of the second package substrate 200 of the second package structure 22 facing the third surface of the first package substrate 100, forming a fourth sub-conductive connection structure on the third surface of the first package substrate 100, and the third sub-conductive connection structure and the fourth sub-conductive connection structure constitute the second conductive connection structure 150′.

In the present embodiment, the first conductive connection structure 150 and the second conductive connection structure 150′ are conductive bumps, respectively. In some implementations, the material of the first conductive connection structure 150 and the second conductive connection structure 150′ is tin.

As an example, the first conductive connection structure 150 and the second conductive connection structure 150′ controlled collapse connections, respectively. Controlled collapse connections have excellent electrical performance and thermal characteristics, and are also suitable for mass production and conductive to reducing the size and weight of package structures.

In the present embodiment, the first conductive connection structure 150 and the second conductive connection structure 150′ are formed using a conductive bump process.

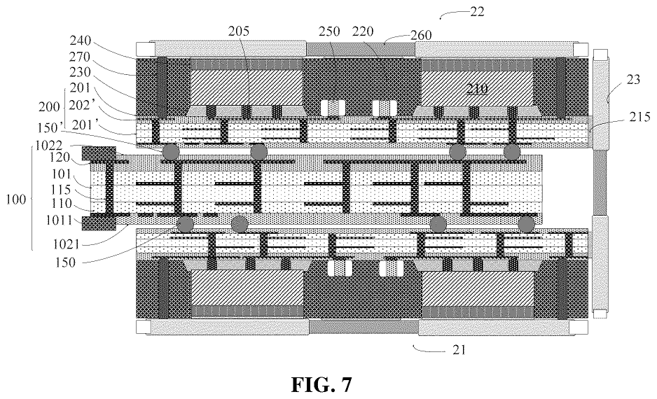

FIGS. 6 to 7 illustrate intermediate structural schematic diagrams formed in each step in another embodiment of the package method provided by the present disclosure. The similarities between the present embodiment and the aforementioned embodiment will not be repeated herein.

Referring to FIG. 6, a second chip 23 is provided.

In the present embodiment, the second chip 23 is different from the first chip 210 in the first package structure 21 and the first chip 210 in the second package structure 22, respectively.

Referring to FIG. 7, after welding the first package structure 21 on the second surface of the first package substrate 100, and welding the second package structure 22 on the third surface of the first package substrate 100, and achieving electrical connections of the first package structure 21 and the second package structure 22 with the first package substrate 100, respectively, the second chip 23 is welded together with the fourth surface of the second package substrate 200 of the first package structure 21 and the fourth surface of the second package substrate 200 of the second package structure 22, respectively, and electrical connections of the second chip 23 with the second package substrate 200 of the first package structure 21 and the second package substrate 200 of the second package structure 22 are achieved.

In the present embodiment, the step of welding the second chip 23 together with the fourth surface of the second package substrate 200 of the first package structure 21 and the fourth surface of the second package substrate 200 of the second package structure 22, respectively, and achieving electrical connections of the second chip 23 with the second package substrate 200 of the first package structure 21 and the second package substrate 200 of the second package structure 22 includes: forming a fourth conductive connection structure 215 on a surface of the second package substrate 200 of the second chip 23 facing the second package substrate 200 of the first package structure 21 and the second package substrate 200 of the second package structure 22; welding the second chip 23 together with the fourth surface of the second package substrate 200 of the first package structure 21 and the fourth surface of the second package substrate 200 of the second package structure 22 through the fourth conductive connection structure 215, respectively, and achieving electrical connections of the second chip 23 with the second package substrate 200 of the first package structure 21 and the second package substrate 200 of the second package structure 22, respectively.

In other embodiments, in the step of welding the second chip together with the fourth surface of the second package substrate of the first package structure and the fourth surface of the second package substrate of the second package structure, respectively, and achieving electrical connections of the second chip with the second package substrate of the first package structure and the second package substrate of the second package structure, respectively, the fourth conductive connection structure can further be formed on the fourth surface of the second package substrate of the first package structure and the fourth surface of the second package substrate of the second package structure, respectively, or a first sub-conductive connection structure is formed on a surface of the second package substrate of the first package device structure facing the second surface of the first package substrate, and a sixth sub-conductive connection structure is formed on the fourth surface of the second package substrate of the first package structure and the fourth surface of the second package substrate of the second package structure, and the fifth sub-conductive connection structure and the sixth sub-conductive connection structure constitute the fourth conductive connection structure.

As an example, the fourth conductive connection structure 215 is a solder ball or a bump. Correspondingly, the fourth conductive connection structure 215 is formed using a ball planting process or a conductive bump process.

The second chip 23 is electrically connected with the second package substrate 200 of the first package structure 21 and the second package substrate 200 of the second package structure 22, respectively, thereby achieving electrical connection with the first package structure 21 and the second package structure 22.

The second chip 23 is welded together with the fourth surface of the second package substrate of the first package structure 21 and the fourth surface of the second package substrate 200 of the second package structure 22, respectively, and is electrically connected with the second package substrate 200 of the first package structure 21 and the second package substrate 200 of the second package structure 22, respectively, which is conductive to improving the integration level of the stacked package structure.

In other embodiments, the third device structure may also be a package structure or a passive component.

The above implementations of the present disclosure are combinations of components and characteristics of the disclosure. Unless otherwise mentioned, components or characteristics may be considered selective. Each components or characteristics may be implemented without combination with other components or characteristics. Additionally, implementations of the present disclosure may be constructed by combining a part of components and/or characteristics. The sequence of operations described in implementations of the disclosure may be rearranged. Some constructions of any implementation may be included in another implementation and may be substituted by corresponding constructions of another implementation. It is obvious to those skilled in the art that the claims that do not have a clear reference relationship with each other in the appended claims may be combined to form implementations of the present disclosure, or may be included as new claims in amendments after filing the present application.

The above description of the disclosed embodiments enables those skilled in the art to achieve or use the present disclosure. Various modifications to these embodiments will be apparent to those skilled in the art, and the general principles defined herein may be implemented in other embodiments without departing from the spirit or scope of the present disclosure. Therefore, the present disclosure will not be limited to the embodiments shown herein, but will be within the widest scope consistent with the principles and novel characteristics disclosed herein.

Although the present disclosure is disclosed as above, the present disclosure is not limited to this. Any skilled in the art may also make various changes and modifications without departing from the spirit and scope of the present disclosure, therefore the scope of protection of the present disclosure should be based on the scope defined by the claims.

What is claimed is:

1. A stacked package structure, comprising:
a first package substrate comprising a first surface and a plurality of first welding surfaces, wherein a signal connection end is arranged on the first surface of the first package substrate; and
a plurality of device structures each corresponding to one of the plurality of first welding surfaces, wherein the plurality of device structures are welded on the first welding surfaces of the first package substrate and electrically connected to the first package substrate.

2. The stacked package structure according to claim 1, wherein each of the plurality of device structures comprises: a chip package structure or a chip.

3. The stacked package structure according to claim 2, wherein:
the plurality of first welding surfaces comprise a second surface and a third surface arranged opposite to the second surface; and
the plurality of device structures comprise:
a first package structure welded on the second surface of the first package substrate and electrically connected with the first package substrate; and
a second package structure welded on the third surface of the first package substrate and electrically connected with the first package substrate.

4. The stacked package structure according to claim 3, further comprising:
a first conductive connection structure between the first package structure and the second surface of the first package substrate, configured to weld the first package structure on the second surface of the first package substrate and electrically connect the first package structure to the first package substrate; and
a second conductive connection structure between the second package structure and the third surface of the first package substrate, configured to weld the second package structure on the third surface of the first package substrate and electrically connect the second package structure to the first package substrate.

5. The stacked package structure according to claim 3, wherein the first surface is a side surface of the first package substrate, the second surface is a back surface of the first package substrate, and the third surface is a front surface of the first package substrate.

6. The stacked package structure according to claim 3, wherein each of the first package structure and the second package structure comprises:
a second package substrate comprising a second welding surface;
a first chip welded on the second welding surface of the second package substrate and electrically connected to the second package substrate; and
a molding layer on the second package substrate, covering the first chip.

7. The stacked package structure according to claim 6, wherein each of the first package structure and the second package structure further comprises:
a third conductive connection structure between the first chip and the second package substrate, configured to weld the first chip on the second welding surface of the second package substrate and electrically connect the first chip to the second package substrate.

8. The stacked package structure according to claim 7, wherein each of the first package structure and the second package structure further comprises:
an underfill layer between the first chip and the second package substrate and filled in gaps between the third conductive connection structures.

9. The stacked package structure according to claim 6, wherein each of the first package structure and the second package structure further comprises:
a first passive component on the second package substrate, exposed by the first chip and electrically connected to the second package substrate.

10. The stacked package structure according to claim 6, wherein each of the first package structure and the second package structure further comprises:
a second passive component above the first chip, electrically connected to the second package substrate.

11. The stacked package structure according to claim 10, wherein each of the first package structure and the second package structure further comprises:
a connection pillar on the second package substrate, exposed by the first chip and electrically connecting the second passive component to the second package substrate.

12. The stacked package structure according to claim 10, wherein each of the first package structure and the second package structure further comprises:
an adhesive layer between the second passive component and the first chip, configured to adhere the second passive component to the first chip.

13. The stacked package structure according to claim 6, wherein:
a surface of the second package substrate facing away from the first surface of the first package substrate is a fourth surface; and
the stacked package structure further comprises:
a third device structure welded on the fourth surface of the second package substrate of the first package structure and the fourth surface of the second package substrate of the second package structure, and electrically connected to the second package substrate of the first package structure and the second package substrate of the second package structure.

14. The stacked package structure according to claim 13, further comprising:
a fourth conductive connection structure between the third device structure and the fourth surface of the second package substrate of the first package structure and the fourth surface of the second package substrate of the second package structure,
wherein the fourth conductive connection structure is configured to weld the third device structure on the fourth surface of the second package substrate of the first package structure and the fourth surface of the second package substrate of the second package structure, and electrically connect the third device structure to the second package substrate of the first package structure and the second package substrate of the second package structure.

15. The stacked package structure according to claim 13, wherein the third device structure comprises: a chip package structure, a chip, or a passive component.

16. A package method, comprising:
providing a first package substrate comprising a first surface and a plurality of first welding surfaces, wherein a signal connection end is arranged on the first surface of the first package substrate;
providing a plurality of device structures, wherein each of the plurality of device structures corresponds to one of the plurality of first welding surfaces; and
welding each of the plurality of device structures on the corresponding first welding surfaces of the first package substrate and electrically connecting the plurality of device structures to the first package substrate.

17. The package method according to claim 16, wherein each of the plurality of device structures comprises a package structure or a chip.

18. The package method according to claim 17, wherein:
the plurality of first welding surfaces comprises a second surface and a third surface arranged opposed to the second surface;
providing the plurality of device structures comprises: providing a first package structure and a second package structure; and
welding each of the plurality of device structures on the corresponding first welding surfaces of the first package substrate and electrically connecting the plurality of device structures to the first package substrate comprises: welding the first package structure and the second package structure on the second surface and the third surface of the first package substrate and electrically connecting the first package structure and the second package structure to the first package substrate.

19. The package method according to claim 18, wherein the providing the first package structure and the second package structure comprises:
providing a second package substrate comprising a welding surface;
welding a first chip on the welding surface of the second package substrate and electrically connecting the first chip to the second package substrate; and
forming a molding layer on the second package substrate to cover the first chip.

20. The package method according to claim 19, wherein a surface of the second package substrate facing away from the first surface of the first package substrate is a fourth surface; and the method further comprises:
providing a third device structure; and
after welding the first package structure and the second package structure, welding the third device structure on the fourth surface of the second package substrate of the first package structure and the fourth surface of the second package substrate of the second package structure and electrically connecting the third device structure to the second package substrate of the first package structure and the second package substrate of the second package structure.
